(19) United States
(12) Patent Application Publication
(10) Pub. No.: US 2024/0420956 A1
(43) Pub. Date: Dec. 19, 2024

(54) Scalable Self-assembly Technique for Strain-Engineering of Amorphous Complex Oxides and Fabrication of Hybrid Superlattices

(71) Applicant: UNM Rainforest Innovations, Albuquerque, NM (US)

(72) Inventors: Francesca Cavallo, Albuquerque, NM (US); Divya Prakash, Albuquerque, NM (US)

(73) Assignee: UNM Rainforest Innovations, Albuquerque, NM (US)

(21) Appl. No.: 18/641,282

(22) Filed: Apr. 19, 2024

Related U.S. Application Data
(60) Provisional application No. 63/497,190, filed on Apr. 19, 2023.

(51) Int. Cl. H01L 21/02

(52) U.S. Cl. CPC H01L 21/02565; H01L 21/02606

(57) ABSTRACT

A system and method to create small curvature assemblies having alternating layers of different amorphous complex oxides as well as amorphous complex oxides and single-crystalline or polycrystalline materials in a radial geometry. The present invention uses complex-oxide-based nanomembranes (NMs) to form rolled-up tubes with sub-micron diameters driven by the large stresses induced by the structural reconfiguration of the oxides during annealing.

### RELATED APPLICATIONS

This application claims priority to U.S. Provisional Application No. 63/497,190, filed on Apr. 19, 2023, which is incorporated herein in its entirety.

### STATEMENT REGARDING FEDERALLY SPONSORED RESEARCH & DEVELOPMENT

This invention was made with government support by the Department of Energy (DOE), Office of Science, Basic Energy Sciences (BES), under Award No. DE-SC0020186 (electron microscopy, data analysis, and mechanical modeling) and by the National Science Foundation (NSF) under Award No. DMR-1720415. The government has certain rights in the invention.

### INCORPORATION BY REFERENCE OF MATERIAL SUBMITTED ON A COMPACT DISC

Not applicable.

### BACKGROUND OF THE INVENTION

Inorganic nanomembranes (NMs) are nanoscale-thickness sheets of amorphous, polycrystalline, or single-crystalline materials that are freestanding either at a stage in their fabrication, in their final state, or both. NMs with thicknesses in the range of a few nanometers to a few hundred nanometers can be isolated from their substrates through synthesis and processing techniques that have become established in the last twenty years. The lateral dimensions of NMs are at least two orders of magnitude larger than their thickness, making them a distinctive platform from 0D, 1D, and bulk materials.

NMs enable a vast range of possibilities, including (i) the capability to subject materials to elastic strain fields with magnitudes or geometries that are not realizable in bulk materials or by direct growth; (ii) unique and rapid characterization of materials properties and kinetic processes; (iii) heterogeneous integration of materials via controlled transfer, including into environments in which the NM materials would be otherwise inaccessible via synthesis; (iv) 3D structures that can be processed in parallel on large-area substrates and can find use in several applications.

The scope of applications and phenomena that benefit from NMs can be extended to a new spectrum of materials and assembly processes by incorporating layers of amorphous complex oxides. Self-assembly of single-crystalline complex oxides into rolled-up 3D structures with microscale diameter has been demonstrated before. In processes employing single-crystalline oxides, the driving force for the assembly of NMs is the lattice mismatch between two or more layers. Thus, approaches to self-assembly that rely on epitaxial growth limit the composition of the NM materials, the lattice mismatch between the layers, and the substrate surface that the NMs can be grown on. Additionally, the properties of crystalline oxides are fixed during their deposition, permitting static assembly but not allowing further changes in the stress distribution. Amorphous oxide layers are not subject to the constraints imposed by epitaxial synthesis, thereby creating novel pathways to synthesize hybrid functional materials on new substrates and with post-assembly tunability of the geometry.

### BRIEF SUMMARY OF THE INVENTION

In one embodiment, the present invention concerns a system and method to create small curvature assemblies having alternating layers of different amorphous complex oxides as well as amorphous complex oxides and single-crystalline or polycrystalline materials in a radial geometry.

In other embodiments, the present invention uses complex-oxide-based nanomembranes (NMs) to form rolled-up tubes with sub-micron diameters driven by the large stresses induced by the structural reconfiguration of the oxides during annealing.

In other embodiments, amorphous layers are initially deposited in a metastable configuration and generate stress through processes that drive them toward equilibrium. Amorphous complex oxide thin films exhibit a range of structural changes that can be induced by heating after depositions. The change in atomic bonding during the reconfiguration of the amorphous oxide provides very large stress available for assembly. The metastability of this state allows kinetic phenomena to be selected to guide crystallization towards desired configurations, including nanoscale single crystals, metastable chemical phases, and thin-film heterostructures. The incorporation of amorphous layers as metastable controlled sources of stress is broadly applicable to obtaining alternating layers of amorphous, polycrystalline, or single-crystalline complex oxides with a wide palette of materials.

Self-assembly of epitaxially grown complex oxides into 3D structures has been demonstrated before. Lattice mismatch between two complex oxide layers was the driving force for the assembly of complex oxide bilayers into rolled-up tubes with microscale diameters. However, epitaxial processes limit the composition of the NM materials, the lattice mismatch between the layers, and the substrate surface that the NMs can be grown on. Employing amorphous oxide layers relaxes these constraints, thereby creating novel pathways to synthesize a wide palette of hybrid functional materials.

In other embodiments, the present invention imparts a high stress and stress gradient in amorphous complex oxides via batch fabrication of devices on conventional semiconductor substrates.

In other embodiments, the present invention enables the reconfiguration of amorphous complex oxides by providing a readily controllable source of stress that can be leveraged in nanoscale assembly to access a broad range of 3D geometries and hybrid materials.

In other embodiments, the present invention concerns SrTiO₃/Si/Si₁₋ₓGeₓ NMs that form rolled-up tubes with sub-micron diameters that are determined by the large stresses arising from structural reconfiguration in the amorphous oxide. SrTiO₃/Si/Si₁₋ₓGeₓ NMs roll up into micron-scale diameter tubes upon release from the growth substrate due to the elastic relaxation of stress from two sources: the epitaxial mismatch of Si₁₋ₓGeₓ and Si and stress in the as-deposited amorphous SrTiO₃. The released NMs are in a metastable structural configuration because the SrTiO₃ layer remains in the initially deposited amorphous state. The curvature of the NMs depends on the stresses in the layers. Heating the hybrid oxide/semiconductor tubes leads to a change in stress due to the reconfiguration of the SrTiO₃ layer and a simultaneous change in the curvature of the NM. Continuum mechanics calculations indicate that the relaxation of the hybrid NM during heating induces large irreversible compressive stress in thethe amorphous oxide. X-ray reflectivity (XRR) and wafer curvature measurements before and after heating show that the densification of the amorphous oxide film is responsible for the development compressive stress in the complex oxide.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1. Freestanding nanosheet including a metastable amorphous layer atop a single-crystalline semiconductor layer before and after heating. For heating parameters (e.g., temperature, duration, heating mode, etc.) that lead to densification of the amorphous film, axial forces (F₁, F₂) and a corresponding torque (M) are generated and drive bending of the nanosheet in the direction perpendicular to its surface. Note that a bilayer with a slight downward bending is shown here before heating to illustrate the change occurring during the heat treatment more clearly.

FIGS. 2A, 2B and 2C. Complex oxide/semiconductor NMs rolled-up tubes. (a) Initial SrTiO₃/Si:B/Si₁₋ₓGeₓ:B/i-Si/Si heterostructure. (b) Mechanical patterning to allow etchant to reach the i-Si sacrificial layer. (c) Rolled-up tube formed by a 14.5 nm SrTiO₃/7.3 nm Si:B/7.2 nm Si_{0.72}Ge_{0.28}:B NM after selective etching of the i-Si sacrificial layer. The tube diameter is D₀ μm=2.2 μm.

FIGS. 3A and 3B. Complex oxides/semiconductor NMs after release and heating. Schematic and off-axis SEM of a 14.5 nm SrTiO₃/7.3 nm Si:B/7.2 nm Si_{0.72}Ge_{0.28}:B NM after (a) selective etching of the i-Si sacrificial layer and (b) after 5 min annealing at 600° C. in a (3:1) flowing N₂:O₂ environment at 1 atm.

FIGS. 4A, 4B, 4C and 4D. Tube diameters at room temperature before and after heating at 600° C. for a) 5 min and b) 2 h in a (3:1) flowing N₂:O₂ environment at 1 atm. The points are measured diameters for individual tubes. Rectangular boxes indicate minimum, 25%, 50%, 75%, and maximum points within the distribution of diameters. An open square indicates the average of the diameters for each condition. The layer structures used here are nominally identical to the ones described in FIGS. 1 and 2.

FIG. 5. Semiconductor/complex oxide heterostructure with thickness discretized into N sub-layers with smaller steps than the individual layer thicknesses. The cartesian coordinate system is highlighted. The coordinates axes follow the NM as it is released and bends out of the initial x-z plane.

FIGS. 6A, 6B, 6C and 6D. Structural characterization of a representative SrTiO₃/Si:B/Si₁₋ₓ Geₓ:B heterostructure. (a) XRD pattern and fit for the Si:B/Si₁₋ₓGeₓ:B heterostructure. The estimated layer structure from fitting the XRD patterns is 7.2 nm Si:B/7.3 nm Si_{0.72}Ge_{0.28}:B on a Si substrate. (b) Surface topography of a released and bonded back SrTiO₃/Si:B/Si₁₋ₓGeₓ:B NM onto a bulk Si substrate. (c) Cross-sectional profiles along regions 1, 2, and 3 in (b). (d) Bright-field cross-sectional transmission electron micrograph of a SrTiO₃/Si:B/Si₁₋ₓGeₓ:B heterostructure. The image shows that 2.8 nm oxide forms at the interface between the SrTiO₃ and the Si layers.

FIGS. 7A, 7B, 7C and 7D. Nanoindentation and estimated elastic modulus of amorphous SrTiO₃. (a) Schematic cross-section of the nanoindentation measurement of amorphous SrTiO₃. (b) AFM image showing the surface topography at the indentation site after indentation with a maximum load of 201 μN. (c) Loading/unloading curves. (d) Elastic modulus as a function of contact depth determined from the experimental data using the Oliver and Pharr model. The dashed line indicates the modulus of the bulk Si substrate.

FIGS. 8A, 8B, 8C and 8D. Relaxation pathway and axial strain distribution in rolled-up semiconductor/complex oxide NMs. Illustration of a SrTiO₃/SiO₂/Si:B/Si₁₋ₓGeₓ:B NM and axial strain profiles in the NMs after release ((a) and (b)) and after heating from 20 to 600° C., 5 min at 600° C., and cooling from 600 to 20° C. ((c) and (d)). The axial strain is plotted as a function of distance from the outer surface of the scroll in the tangential (x), radial (y), and longitudinal directions (z) of the tube. The axial strain profiles in (b) and (d) were obtained using the measured tube diameters D₀ μm=2.4 μm and D₁ μm=0.9 μm, respectively. In our calculations we used a 14.5 nm/2.8 nm/7.1 nm/7.1 nm SrTiO₃/SiO₂/Si:B/Si_{0.72}Ge₂₈:B heterostructure based on the results in FIG. 6.

FIGS. 9A. 9B and 9C. Characterization of amorphous SrTiO₃ before and after heating. (a) GIXRD pattern acquired from as-deposited amorphous SrTiO₃ and after heating to 600° C. for 5 min under a (3:1) N₂:O₂ gas flow at 1 atm. (b) XRR measurements of as-deposited amorphous SrTiO₃/Si and after heating to 600° C. for 5 min under a (3:1) N₂:O₂ gas flow at 1 atm. The simulations use the parameters given in Table 1. The inset shows the structure of the simulated sample. (c) Stress in SrTiO₃ layer determined using wafer curvature of SrTiO₃/bulk Si after heating at 600° C. for 2 h in air. The measurements were performed along with two perpendicular directions over an area of 8×8 mm² as shown in the inset. All measurements whose results are shown in (a)-(c) were performed after cooling the samples to room temperature.

FIGS. 10A and 10B. (a) Schematic of a rolled-up SrTiO₃/Si NM after heating at 600° C. and subsequent cooling to 20° C. Calculated axial strain in the tangential (x), radial (y), and longitudinal (z) directions for a 14.5/10 nm SrTiO₃/Si NM. The calculated tube diameter after heating was D₁^{c}=1.1 μm with the NM bending upward, i.e., away from the substrate surface. A 2.8 nm-thick SiO₂ layer at the Si/SrTiO₃ interface was also included in the calculations.

FIGS. 11A, 11B, 11C and 11D. Tunability of strains and strain gradients via reconfiguration-driven assembly of NMs. (a)-(b) Calculated axial strain in the tangential direction (a) and the radial direction (b) for SrTiO₃/Si NMs with three different total thicknesses and =1 after heating at 600° C. and subsequent cooling to 20° C. (c) Tangential strain gradient as a function of R at three different total thicknesses of the NM. (d) Schematic of a selected region of the rolled-up SrTiO₃/Si NM with two different β. The red arrows specify the direction of the compressive force arising during heating. The red dotted line and the blue dash-dotted line mark the middle of the SrTiO₃ layer and the SrTiO₃/Si NMs, respectively. d₁ and d₂ are the arms of the bending torque in the two cases.

FIGS. 12A, 12B and 12C. Assembly of amorphous complex oxide heterostructures and residual stress in the tube wall. (a) Schematic illustration of a self-assembled SrTiO₃/LaAlO₃ NM showing that the NM is expected to be bent downward after both release and heating. Calculated axial strain profiles in a 14.5 nm SrTiO₃/10 nm LaAlO₃ μNM after release (b) and after heating at 600° C. and subsequent cooling to 20° C. (c). The axial strain was calculated in the tangential (x), radial (y), and longitudinal (z) directions. The calculated tube diameter after release and after release and heating were D₀^{c}=77.5 μm and D₁^{c}=1.2 μm, respectively.

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure, or system. Further, the terms and phrases used herein are not intended to be limiting, but rather to provide an understandable description of the invention.

In one embodiment, the present invention concerns the self-assembly of complex oxide-based nanomembranes (NMs) in radial geometries, including radially stacked complex oxides and complex oxides/single-crystalline semiconductors superlattices. These structures will offer a tremendous opportunity for discovery-driven science and new functionalities.

For example, the proximity of single-crystalline semiconductors and complex oxides will potentially result in superlattices with intriguing magnetic and electronic properties through modulating the oxides' intrinsic spin-lattice coupling and other coupling effects. Moreover, we expect that curvature will significantly affect the electronic band structure of the stack and produce unique electrical and thermal transport features.

Amorphous SrTiO₃/Si/Si₁₋ₓGeₓ nanomembranes (NMs) roll up into micron-scale tubes upon release from the growth substrate due to the elastic relaxation of stress from two sources: (i) the epitaxial mismatch of SiGe and Si and (ii) stress resulting from the deposition of the amorphous SrTiO₃. Crucially, the NMs are in a metastable structural configuration after release because the SrTiO₃ layer remains in the amorphous state. Heating transforms NMs scrolls into swiss roll structures that alternate single-crystalline semiconductors and amorphous complex oxides in a radial geometry.

A detailed continuum mechanics study establishes that the relaxation of the hybrid NM during heating involves large irreversible compressive stress arising from structural changes in the oxide. Mechanical modeling also shows that this stress is responsible for NM assembly. X-ray reflectivity, x-ray diffraction, and transmission electron microscopy probe changes in the structure of the SrTiO₃ layer that is consistent with densification of the complex oxide.

The various embodiments of the present invention may produce a variety of complex oxides-based heterostructures via reconfiguration-driven assembly of amorphous oxides, including SrTiO₃/Si and SrTiO₃/LaAlO₃.

In another embodiment, the present invention provides an amorphous SrTiO₃ layer on a Si:B/Si₁₋ₓGeₓ:B heterostructure that is reconfigured at the atomic scale upon heating, exhibiting a change in volume of ˜2% percent and accompanying biaxial stress. The Si:B/Si₁₋ₓGeₓ:B bilayer is fabricated by molecular beam epitaxy, followed by sputter deposition of SrTiO₃ at room temperature. The processes yield a hybrid oxide/semiconductor nanomembrane. Upon release from the substrate, the nanomembrane rolls up and has a curvature determined by the stress in the epitaxially grown Si:B/Si₁₋ₓGeₓ:B heterostructure. Heating to 600° C. leads to a decrease of the radius of curvature consistent with the development of a large compressive biaxial stress during the reconfiguration of SrTiO₃. The control of stresses via post-deposition processing provides a new route to the assembly of complex oxide-based heterostructures in 3D geometry. The reconfiguration of metastable mechanical stressors enables (i) synthesis of various types of strained superlattice structures that cannot be fabricated by direct growth and (ii) technologies based on strain-engineering of complex oxides via highly scalable lithographic processes and on large-area semiconductor substrates.

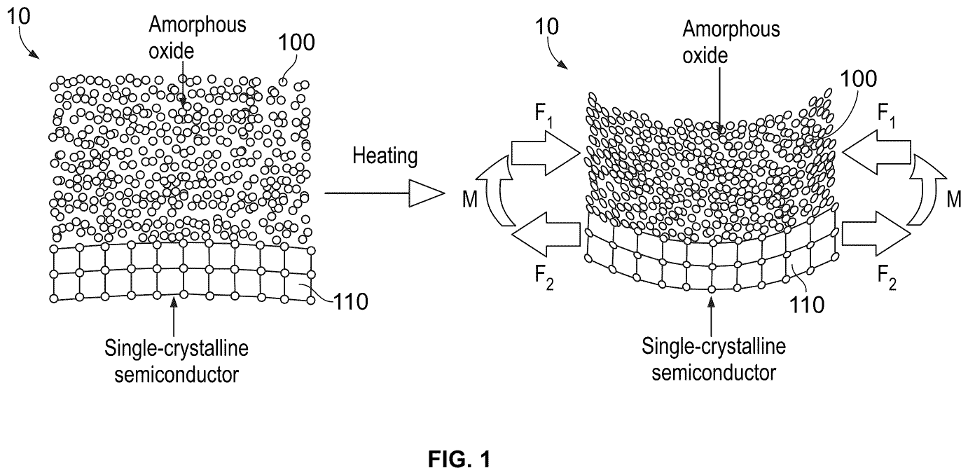

FIG. 1 illustrates the effect of heating a freestanding nanosheet 10 that includes a metastable amorphous film 100 and a single-crystalline film 110. The assumption is that amorphous film 100 undergoes densification when heated at sufficiently high temperatures to rearrange chemical bonds. An average compressive force (F₂) is thus generated in the amorphous layer 100, and an average reaction force (Fi) arises in the single-crystalline semiconductor 110. The two forces form a torque (M) that bends the nanosheet 10 perpendicularly to its surface.

The reconfiguration of amorphous oxides provides a route to synthesizing strained superlattice structures and geometries that cannot be obtained by direct growth. The phenomenon also creates opportunities to strain engineer a broad palette of amorphous complex oxides via fabrication of 3D structures on large-area semiconductor substrates. Finally, self-assembly of NMs in 3D structures serves as a sensitive scientific probe of atomic-scale processes. Dramatic changes in the atomic configuration accompany interface formation, the relaxation of glassy states, and crystallization. The bonding in amorphous form is incomplete yielding stress that varies during reconfiguration and relaxation. Rolled-up NMs may serve as probes to measure film stress evolution during the structural transformation of complex oxides and provide insight into the fundamental mechanisms involved in such structural transformation.

### Reconfiguration-Induced Assembly of Complex Oxide/Semiconductor Nanomembranes

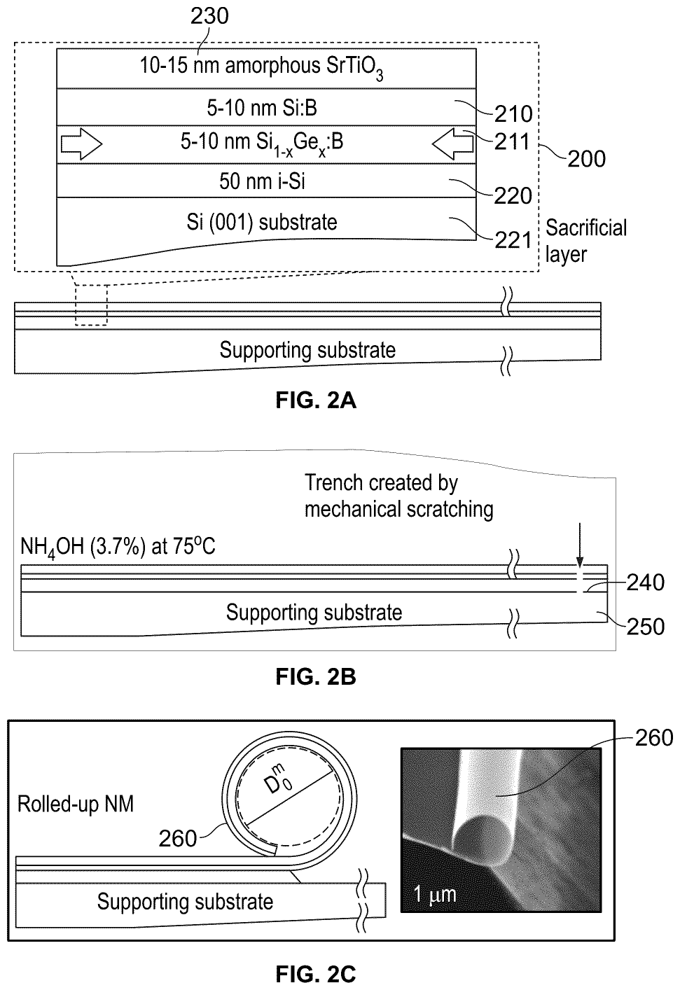

Amorphous oxide/semiconductor NMs were fabricated from the planar configuration 200 shown in FIG. 2(a). The initial structure consisted of highly B-doped Si/Si₁₋ₓGeₓ (Si:B/Si₁₋ₓGeₓ: B) bilayers 210-211 coherently grown by molecular beam epitaxy (MBE) on intrinsic Si (i-Si) sacrificial layers 220. The substrate was a p-type bulk Si (001) wafer 221. The Si:B/Si₁₋ₓGeₓ:B layers 210-211 were thinner than the critical thickness for strain relaxation through dislocation formation. The i-Si sacrificial layer 220 was 50 nm thick. In this particular embodiment, a 7.3 nm Si:B/7.2 nm Si_{0.72}Ge_{0.28}:B bilayer 210-211 grown onto the i-Si/p-Si substrate 220-221 combination was used. The biaxial strains in the Si_{0.72}Ge_{0.28}:B and the Si:B layers 210-211 were −1.1% and zero, respectively.

Simultaneous deposition of Si, Ge, and B achieved a B concentration in the range of 1.5-1.8×10²⁰ cm⁻³. An amorphous SrTiO₃ layer 230 with a nominal thickness of 10 nm was deposited onto the semiconductor heterostructure.

The oxide/semiconductor NMs were released from the substrate by etching in a 3.7% NH₄OH solution at 75° C., as shown in FIG. 2(b). The etch rates of Si:B and Si_{0.72}Ge_{0.28}:B under these conditions are far lower than that of i-Si. The etchant reached the i-Si sacrificial layer through notches, grooves or scratches 240 introduced along the <100> direction into the surface of the heterostructure 250 using a mechanical stylus. After rinsing in deionized (DI) water and isopropyl alcohol (IPA), scrolls and rolled-up tubes were observed near the mechanical scratches.

FIG. 2(c) shows a rolled-up tube 260 formed by a SrTiO₃/Si:B/Si_{0.72}Ge_{0.28}:B NM. Scanning electron microscopy (SEM) measurements show that the tube diameter is D₀^{c}=2.2 μm. The released NM tubes were heated employing multiple experimental protocols that all yielded similar qualitative changes in the tube structure. The measured tube diameters after release and after heating are termed D₀^{m} and D₁^{m}, respectively.

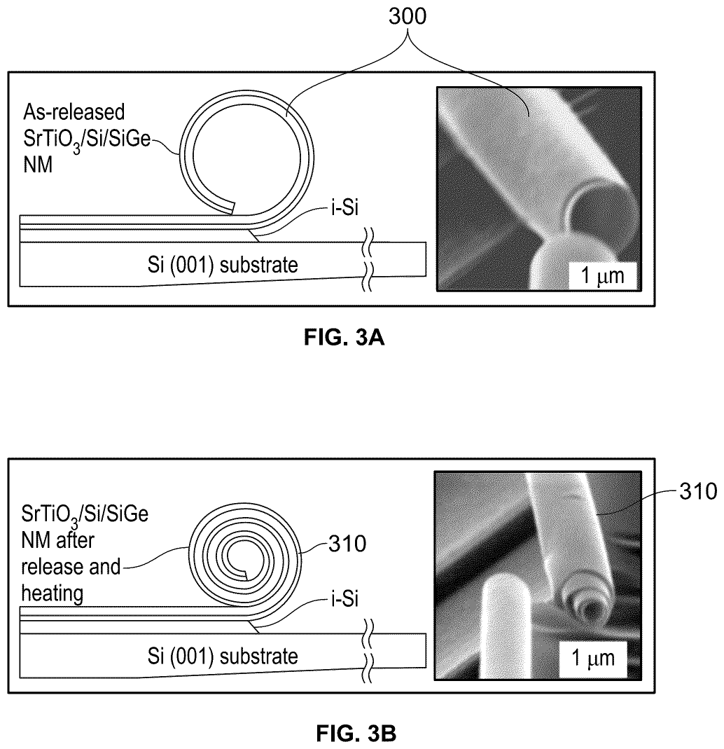

FIG. 3 illustrates the transformation of a selected NM 300 consisting of a 14.5 nm SrTiO₃/7.3 nm Si:B/7.2 nm Si_{0.72}Ge_{0.28}:B heterostructure. The NM 300 tube was heated for 5 min at 600° C. under an N₂:O₂ flow in a 3:1 ratio at atmospheric pressure. For changed tube 310, the diameter changed from D₀ μm=2.0 μm for the as-released NM to D₁^{m}=0.5 μm after heating. In addition to the change in diameter, the NM tubes 300 and 310 in FIGS. 3(a) and 3(b) exhibit different numbers of windings, approximately 1.5 for tube 300. For tube 310, a swiss roll structure is formed as a result of having a plurality of windings. For the embodiment shown, tube 310 has 4 windings.

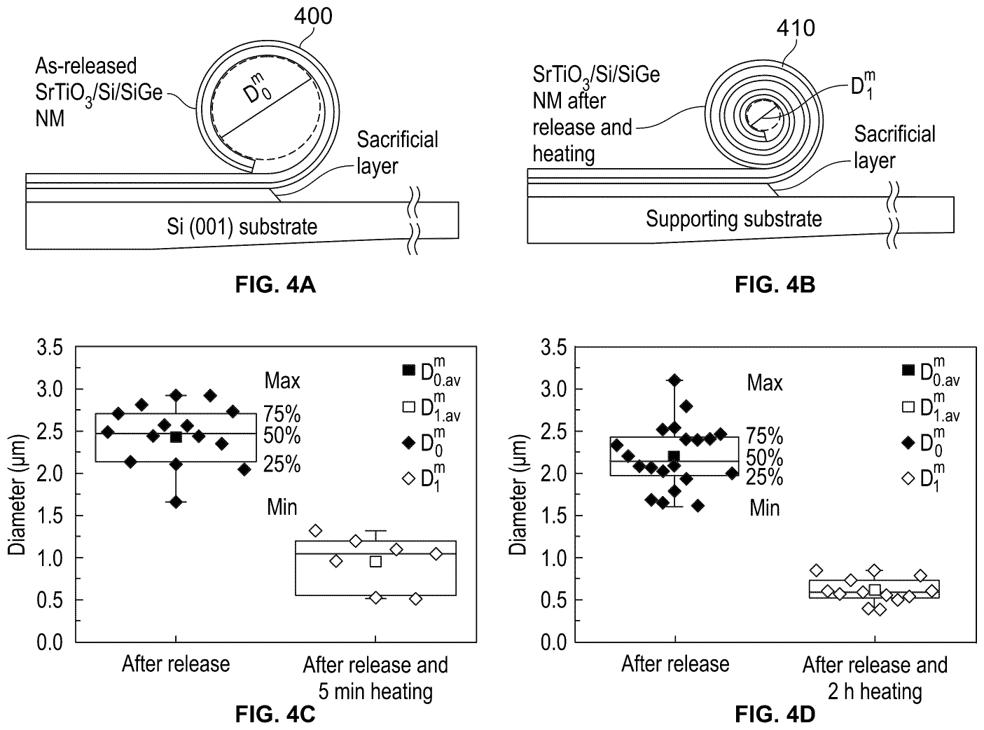

FIG. 4 shows the changes in diameter for two heating durations at 600° C.: 5 min and 2 h. The average diameters were measured for at least seven tubes for each sample. Measured diameters correspond to the inner diameters of the tubes as schematically illustrated in FIG. 4(a) or tube 400 and 4(b) for tube 410.

The fractional change in diameter is ΔD/D=(D_{1,av}−D_{0,av}^{m})/D_{0,av}^{m}, where D_{0,av}^{m}, and D_{1,av}^{m} are the average diameters of the as-released and released and heated NMs, respectively. Both heating durations led to large decreases in the average diameter, from 2.5 μm to 0.9 μm for the samples heated for 5 min at 600° C. and from 2.1 μm to 0.6 μm for samples heated for 2 h at the same temperature. The corresponding values of ΔD/D were −60% and −71%. Control samples consisting of Si:B/Si_{0.28}Ge_{0.72}:B rolled-up tubes with a sub-micron diameter underwent rapid thermal annealing up to 850° C. for times ranging from 1 to 10 min and exhibited no change in diameter after heating.

The structural mechanism linking the reconfiguration of amorphous oxide to the decrease in NM tube diameter is described in detail below. Briefly, predictions based on mechanical models incorporating stresses due to atomic-scale reconfiguration of the amorphous SrTiO₃ layer are consistent with the observed decrease in the tube diameter. XRR and wafer-curvature measurements confirm that densification occurs in the amorphous film.

### Modeling and Discussion

Elastic Model of Nanomembrane Curvature and Residual Strain

The assembly of the oxide/semiconductor NM tubes comprised three steps: (i) growth/deposition of the planar SrTiO₃/Si:B/Si₁₋ₓGeₓ:B heterostructure; (ii) release of the heterostructure from the substrate, and (iii) heating. The present invention modeled the elastic response of the complex oxide/semiconductor heterostructure under conditions corresponding to each stage of the process. For this purpose, the present invention used a plane stress model under a generalized plane strain equilibrium condition. The model calculated the strain distribution in the NM tubes and the residual strain in the amorphous SrTiO₃ layer in its as-deposited state and after heating.

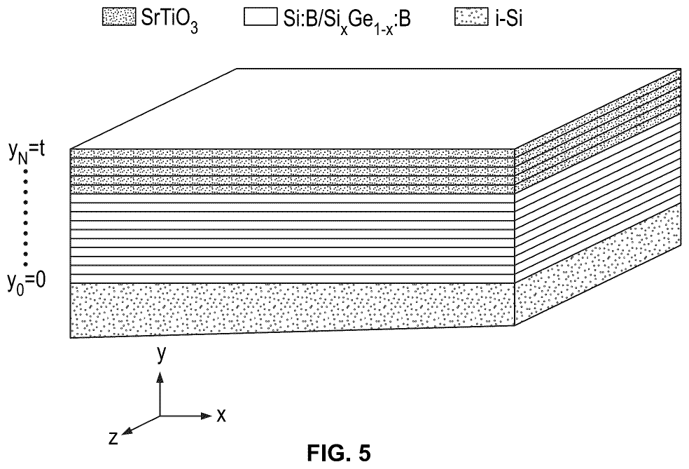

The heterostructure of total thickness, t, was divided into sub-layers with thickness tᵢ=0.1 nm, elastic modulus Eᵢ, and Poisson's ratio, vi, with i=1, 2, . . . , N, where N=t/tᵢ. FIG. 5 specifies the coordinates system for an unreleased complex oxide/semiconductor heterostructure.

Under a generalized plane strain condition and considering a stress σ_{y}=0, the stresses in each sub-layer are:

$${σ}_{i}^{x} = {E}_{i}^{′} {ε}_{i}^{x} + {G}_{i}^{′} {ε}_{i}^{a} - {E}_{i}^{′} {ε}_{i}^{0 , x} - {G}_{i}^{′} {ε}_{i}^{0 , z} , \qquad ( 1 )$$

$${σ}_{i}^{z} = {G}_{i}^{′} {ε}_{i}^{x} + {E}_{i}^{′} {ε}_{i}^{z} - {G}_{i}^{′} {ε}_{i}^{0 , x} - {E}_{i}^{′} {ε}_{i}^{0 , z} , \qquad ( 2 )$$

Where

$${E}_{i}^{′} = \frac{{c}_{11 , i} {c}_{11 , i}^{′} - {c}_{12 , i}^{2}}{{c}_{11 , i}} \qquad ( 3 )$$

$${G}_{i}^{′} = \frac{{c}_{11 , i} {c}_{13 , i}^{′} - {c}_{12 , i}^{2}}{{c}_{11 , i}} \\ for Si : B and {Si}_{1 - x} {Ge}_{x} : B , and \qquad ( 4 )$$

$${E}_{i}^{′} = \frac{{E}_{i}}{1 - {v}_{i}^{2}} , \qquad ( 5 )$$

$${G}_{i}^{′} = \frac{v {E}_{i}}{1 - {v}_{i}^{2}} , \qquad ( 6 )$$

for SrTiO₃. The elastic constants reflect the elastic anisotropy of epitaxial Si:B/Si₁₋ₓGeₓ:B^{[32]} and treat amorphous SrTiO₃ as isotropic.

The strain was defined self-consistently for all the layers using the in-plane linear extent of the layer with respect to its unstressed state. The strain profile in the tube wall was obtained across the total thickness with a step size equal to the thickness of each sublayer. The strain in the i^{th} layer is

$${ε}_{i}^{x} = {c}_{i} + \frac{{y}_{i} - {y}_{b}}{R} , \qquad ( 7 )$$

$${ε}_{i}^{y} = - \frac{{C}_{12}}{{C}_{11}} ( {ε}_{i}^{x} + {ε}_{i}^{z} - {ε}_{i}^{0 , x} - {ε}_{i}^{0 , z} ) + {ε}_{i}^{0 , y} , \qquad ( 8 )$$

$${ε}_{i}^{z} = {d}_{i} , \qquad ( 9 )$$

where cᵢ and dᵢ are the axial strain components along x and z, respectively, y_{b} specifies the position of the neutral plane, and R is the equilibrium radius of curvature.

The values εᵢ^{0,x}, εᵢ^{0,y}, and εᵢ^{0,z} are the initial strains within the itl layer before each step of the NM processing, including release from the substrate surface, heating from room temperature to the annealing temperature, and cooling back to room temperature. The initial strain may originate from lattice mismatch (for single-crystalline materials), different coefficients of thermal expansion (CTE) in bonded layers, bending, deposition stresses, and reconfiguration of amorphous materials. Therefore, initial strains in x, y, and z, are

$${ε}_{i}^{0 , x / 0 , y / 0 , z} = {ε}_{i , epi / dep}^{0 , x / 0 , y / 0 , z} + {ε}_{i , th}^{0 , x / 0 , y / 0 , z} + {ε}_{i , b}^{0 , x / 0 , y / 0 , z} + {ε}_{i , rec}^{0 , x / 0 , y / 0 , z} , \qquad ( 10 )$$

where ε_{i,epi/dep}^{0,x/0,y/0,z} is the strain established during epitaxial growth (for Si:B and Si₁₋ₓGeₓ:B) or deposition (for SrTiO₃), ε_{i,th}^{0,x/0,y/0,z} is the strain arising from the different CTE in the bonded layers, ε_{i,b}^{0,x/0,y/0,z} is the strain due to bending of the NM to a radius of curvature R, and ε_{i,rec}^{0,x/0,y/0,z} is the strain due to reconfiguration of the material atomic structure via densification, crystallization, or interdiffusion. The present invention considered or determined initial strains in Si:B, Si₁₋ₓGeₓ:B, and SrTiO₃ at the various steps of the process.

The force and bending moment equations under a generalized plane strain condition at the equilibrium are:

$${\sum }_{i = 1}^{n} {t}_{i} [ {E}_{i}^{′} {c}_{i} + {G}_{i}^{′} {d}_{i} - {E}_{i}^{′} {ε}_{i}^{0 , x} - {G}_{i}^{′} {ε}_{i}^{0 , z} ] = 0 , \qquad ( 11 )$$

$${\sum }_{i = 1}^{n} {\int }_{{y}_{i - 1}}^{{y}_{i}} \frac{{E}_{i}^{′} ( y - {y}_{b} )}{R} d y = 0 , \qquad ( 12 )$$

$${\sum }_{i = 1}^{n} {\int }_{{y}_{i - 1}}^{{y}_{i}} \text{} [ \text{} {E}_{i}^{′} ( {c}_{i} + \frac{( y - {y}_{b} )}{R} ) + {G}_{i}^{′} {d}_{i} - {E}_{i}^{′} {ε}_{i}^{0 , x} - {G}_{i}^{′} {ε}_{i}^{0 , z} ] \times \text{} ( y - {y}_{b} ) d y = 0 , \qquad ( 13 )$$

$${\sum }_{i = 1}^{n} {\int }_{{y}_{i - 1}}^{{y}_{i}} [ {G}_{i}^{\cdot } ( {c}_{i} + \frac{( y - {y}_{b} )}{R} ) + {E}_{i}^{′} {d}_{i} - {E}_{i}^{′} {ε}_{i}^{0 , z} - {G}_{i}^{′} {ε}_{i}^{0 , x} ] d y = 0. \qquad ( 14 )$$

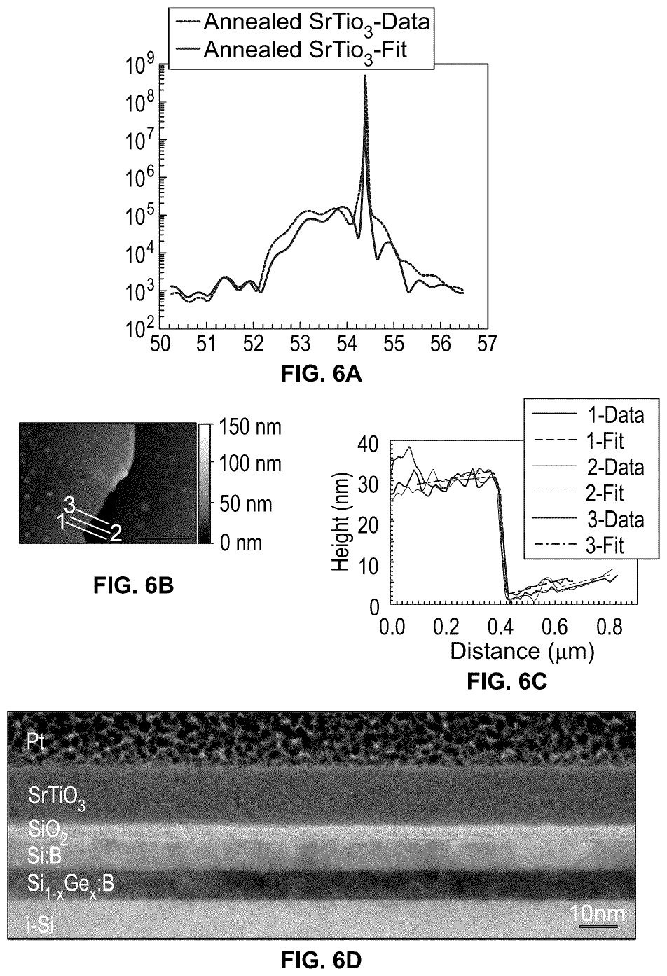

The layer thickness and composition at various stages of the process were measured using XRD, transmission electron microscopy (TEM), and atomic force microscopy (AFM). FIG. 6 shows the structural characterization of a SrTiO₃/Si:B/Si₁₋ₓGeₓ:B heterostructure 600. The XRD patterns in FIG. 6(a) give a heterostructure with thicknesses 7.2 nm Si:B/7.3 nm Si_{0.72}Ge_{0.28}:B. The AFM image and height profile in FIGS. 6(b) and 6(c) show that the total thickness of a NM that has been released and bonded back onto the Si substrate is 30.7±0.2 nm. TEM was used to provide an independent measurement of the layer thicknesses. namely 7.1±0.2 nm, 7.2±0.2 nm, 2.8±0.2 nm, 13.7±0.2 nm for Si1₁₋ₓGeₓ:B, Si:B, SiO₂, SrTiO₃, respectively (see FIG. 6(d)). The observed SiO₂ layer is attributed to the oxidation of the Si surface in air before sputter deposition of the SrTiO₃. The mechanical model included the SiO₂ layer because it affects the equilibrium curvature of the rolled-up NM and the strain distribution in the tube wall.

### Characterization of the Elastic Modulus of Amorphous SrTiO₃

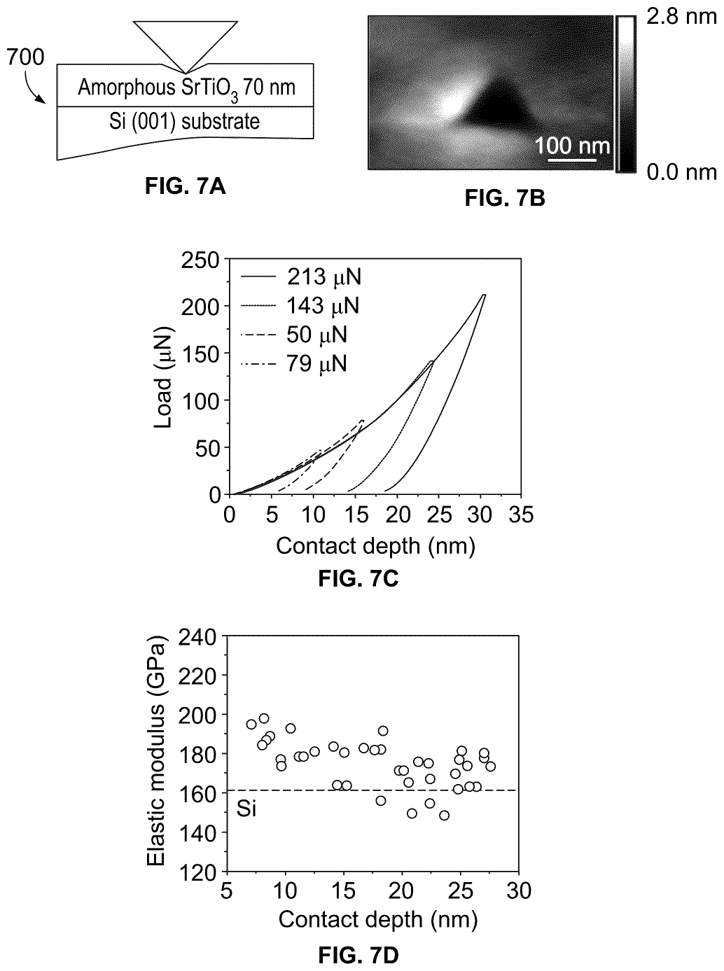

Nanoindentation was used to measure the elastic modulus of amorphous SrTiO₃. A sample consisting of a 70-nm-thick amorphous SrTiO₃ on a 270 μm-thick Si substrate was selected so that the amorphous layer thickness was more than one order of magnitude larger than the minimum indentation depth of 7 nm. Under these conditions, nanoindentation provides a substrate-independent measurement of the SrTiO₃ elastic modulus. FIG. 7(a) shows a cross-sectional schematic of the nanoindentation measurement. The Methods section reports additional details, including the experimental procedure. A scanning probe microscopy image of a selected indented region with a maximum load of 201 μN is in FIG. 7(b).

The loading/unloading curves at various contact depths are continuous without pop-in phenomena for maximum loads ranging from 79 to 213 μN, as in FIG. 7(c), indicating that no fracture occurred during the measurements. The elastic modulus was determined from the experimental data using the Oliver and Pharr model^{[33]} and is plotted in FIG. 7(d) as a function of contact depth. Values of the elastic modulus range between 200 GPa at the shallowest indentation depth, and 160 GPa as the indentation depth increases (see FIG. 7(d)). The extracted modulus at the shallowest indentation depth, 7 nm, represents the substrate-independent elastic modulus of the as-deposited SrTiO₃. The extracted modulus at the highest indentation depths matches previously reported values for bulk Si (i.e., 160 GPa), suggesting that the substrate bears a larger fraction of the load as the vertical displacement increases.

The depth dependence of the elastic modulus shown in FIG. 7(d) can be further understood using a mechanical model of the elastic rebound between an indenter and a layered specimen (see FIG. S1 in the Supporting Information). The results of the indentation model indicate that the elastic modulus of the SrTiO₃ film range from 190 to 210 GPa, closely matching the moduli extracted for the shallowest indentation depths in FIG. 7(d). The elastic modulus of amorphous SrTiO₃ is lower than the modulus of single- and polycrystalline, 225-280 GPa, which suggests that the as-deposited amorphous SrTiO₃ has a lower density than its crystalline counterpart.

### Results of the Elastic Model of NM Curvature and Residual Strain

Equations 11-14 were used to determine the residual strain in the amorphous SrTiO₃ and the strain profile within the NM after release from the substrate surface and after heating from 20 to 600° C. followed by cooling to 20° C.

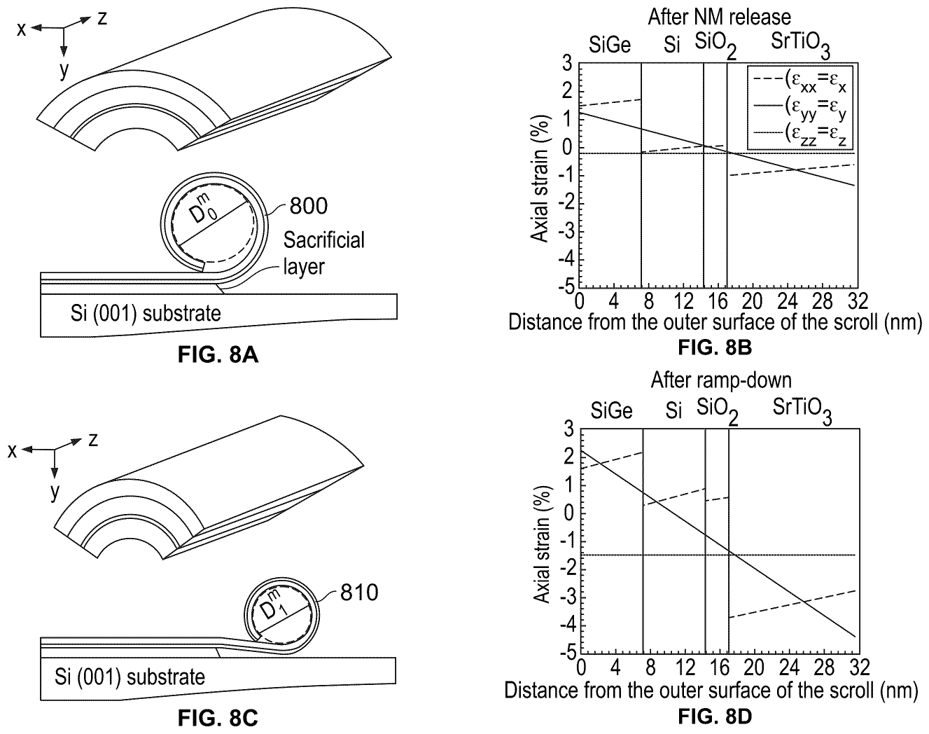

FIG. 8 illustrates the geometry of NM 800 at the selected processing steps. Upon release from the substrate surface, the stressed NM bends upward into a scroll with a microscale diameter (see FIGS. 2(c) and 3(a)). The measured diameter of a representative scroll (D₀ μm=2.4 m) was used to determine the deposition strain in the as-sputtered SrTiO₃ layer. The experimental curvature is matched by a 0.7% average compressive strain in the as-deposited SrTiO₃. The strain profile in the tube wall is shown in FIG. 7(b).

In the following processing step, the rolled-up NM 800 was heated from 20 to 600° C., kept at 600° C. for 5 min and cooled to 20° C. The stress arising in SrTiO₃ during the thermal cycle was determined by constraining the diameter of the rolled-up NM 800 to the measured value after heating (D₁ ^{m}=0.9 μm). The calculations assume that thicknesses, compositions, and mechanical properties of the semiconductor layers within the heterostructure remain unchanged with respect to the as-released state.

The strain arising in the amorphous SrTiO₃ layer during heating to 600° C. and cooling to 20° C. was calculated to be −2.1%. This isotropic and compressive strain in SrTiO₃ drives the NM diameter to the measured experimental value. FIG. 8(d) shows that a remarkably high compressive strain (i.e., ranging from −1.5 to −4.2%) and a strain gradient of −0.2%/nm can be established in the SrTiO₃ layer via assembly into a 3D structure 810 with sub-micrometer diameter.

### Stress due to Amorphous SrTiO₃ Reconfiguration

Mechanical modeling discussed indicates that a significant change in stress and strain occurs in the SrTiO₃ during heating at 600° C. for 5 min. In order to gain more insight into the structural changes that induced compressive stress in the complex oxide during heating, an amorphous SrTiO₃ thin film on a Si substrate was characterized before and after heating to 600° C. using grazing incidence x-ray diffraction (GIXRD) and XRR.

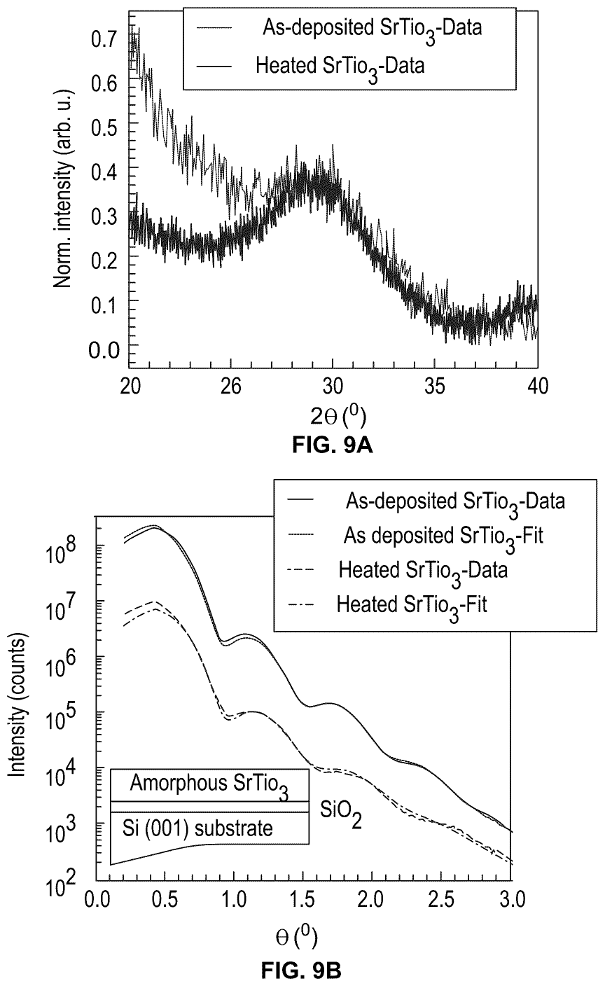

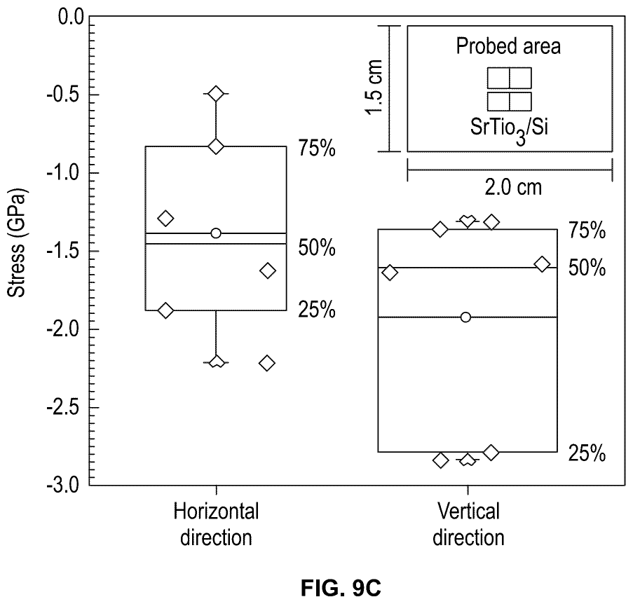

The as-deposited and heated layers both exhibited x-ray scattering patterns consistent with amorphous thin film layers. The GIXRD patterns in FIG. 9(a) were acquired from SrTiO₃/Si before and after heating to 600° C. for 5 min. The GIXRD patterns are dominated by broad peaks at 29.3° arising from amorphous SrTiO₃ and indicate that the complex oxide has not crystallized during the heat treatment.

FIG. 9(b) shows measured and simulated XRR patterns acquired from SrTiO₃/Si before and after heating to 600° C. for 5 min. The simulated XRR curves consider a structure consisting of amorphous SrTiO₃ on a bulk Si (001) with a thin SiO₂ interface layer. The densities of SiO₂ and Si were set to 2.196 and 2.329 g/cm³, respectively. The density of SrTiO₃ was allowed to vary between 4 and 5 g/cm³, the previously reported values for amorphous SrTiO₃ and the ideal density of crystalline SrTiO₃.^{[22]} The reflectivity simulation yielded the parameters shown in Table I.

TABLE 1
Reflectivity fitting parameters for the as-deposited amorphous SrTiO₃ layer
and after heating to 600° C. for 5 min and subsequent cooling to 20° C.

| | SrTiO₃ | SrTiO₃ | SrTiO₃ rms | SiO₂ | SiO₂ | SiO₂ rms | Si | Si | Si rms |
|---|---|---|---|---|---|---|---|---|---|
| Sample | density | thickness | roughness | density | thickness | roughness | density | thickness | roughness |
| type | (g/cm³) | (nm) | (nm) | (g/cm³) | (nm) | (nm) | (g/cm³) | (mm) | (nm) |
| As- | 4.100 | 12.78 | 0.93 | 2.196 | 2.85 | 0.93 | 2.329 | 270 | 0.822 |
| deposited | | | | | | | | | |
| SrTiO₃/Si | | | | | | | | | |
| Heated | 4.316 | 12.01 | 0.85 | 2.196 | 2.90 | 1.56 | 2.329 | 270 | 0.730 |
| SrTiO₃/Si | | | | | | | | | |

The thickness of the SrTiO₃ film decreased by 5.2% after heating to 600° C. for 5 min. This result lies between the 2.3% and 5.5% volume contraction for SrTiO₃/Si after 4 and 8 min at 600° C., respectively. A characteristic nucleation time of 16 min for nanocrystallites of SrTiO₃ on non-epitaxial substrates at 600° C. has also been reported.

The characteristic nucleation time (i.e., the time until the first measurable crystals appear) is significantly larger than the duration of the heating reported here, indicating that the SrTiO₃ has not undergone crystallization. Therefore, reconfiguration of the amorphous layer, rather than crystallization, is responsible for the densification of the SrTiO₃ and the stress that creates large-curvature assemblies.

Wafer curvature measurements using the arrangement described in the Methods section were used to determine an experimental value of the compressive stress arising in the amorphous SrTiO₃ (σ_{SrTiO}_{₃}¹) during heating. The stress in SrTiO₃/Si is calculated from the measured curvature after heating (kₘ¹) using Stoney's equation

$${σ}_{S r T i {O}_{3}}^{1} = \frac{{E}_{Si , sub} {t}_{Si , sub}^{2} {κ}_{m}^{1}}{( 1 - {v}_{Si , sub} ) 6 {t}_{{SrTiO}_{3}}^{1}} , \qquad ( 15 )$$

where E_{Si,sub}, v_{Si,sub}, and t_{Si,sub} are the elastic modulus, Poisson's ratio, and thickness of the Si substrate, and t_{SrTio}_{₃}¹ is the thickness of the SrTiO₃ layer after heating as obtained by XRR. FIG. 9(c) shows that the calculated stress in two perpendicular directions after heating is highly compressive. The stress is consistent with an effect arising from the densification of the SrTiO₃ layer during heating to 600° C. and the lateral constraint imposed by the thin-film geometry. The biaxial stress resulting from heating can be estimated by considering what stress would be required to constrain the reconfigured amorphous layer to its initial dimensions. With an elastic modulus of 200 GPa, as measured above, the densification by 5% would give an upper limit of 10 GPa to the stress. The estimated stress from both the wafer and the rolled-up NM curvatures is on the order of 1-4 GPa, indicating that much of the stress due to the reconfiguration of the amorphous layer is relaxed. Possible relaxation processes include the nanoscale viscous flow of the amorphous layer.

### Tunable Strain Fields in Complex Oxide Rolled-up Nanomembranes: Design and Potential Applications

Reconfiguration-driven assembly of NMs has tremendous potential for enabling strain engineering and batch fabrication of complex oxide-based 3D structures on large-area semiconductor substrates. The embodiments of the present invention demonstrate that small-diameter assemblies can be obtained using different oxide-based NMs and that high strains and strain gradients can be tailored by varying the composition and thickness of the various layers within the NM.

### Assembly and Tunable Strain Fields in SrTiO₃/Si Nanomembranes

The present invention relied on a continuum mechanical model to determine the relaxation pathways for SrTiO₃/Si NMs after release and heating. For this purpose, the present invention utilized the stress that was calculated from the radius of curvature of the rolled-up SrTiO₃/Si:B/Si_{0.72}Ge_{0.28}:B NMs at the various steps of the process. The calculations also used the observed decrease in the SrTiO₃ layer of 5.2% after heating.

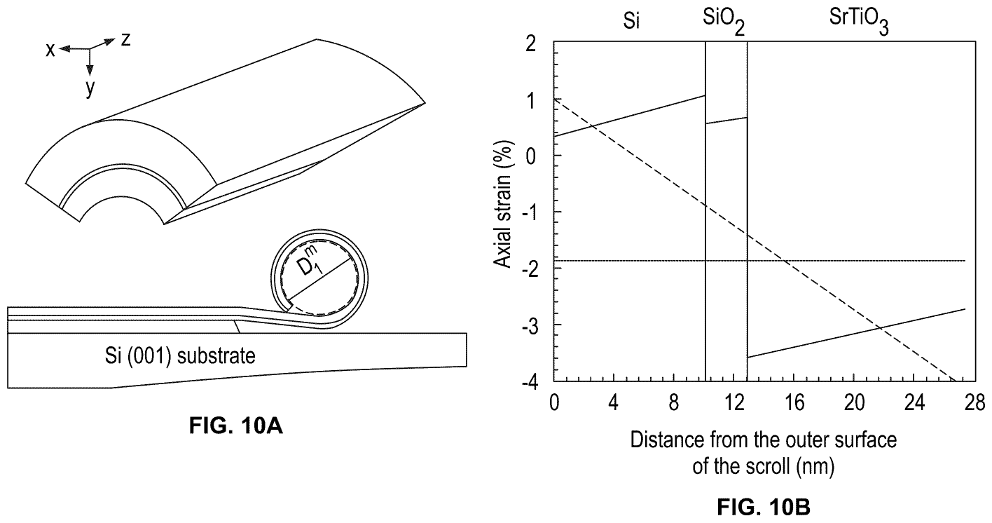

The model determined that a 14.5/10 nm SrTiO₃/Si NM will bend upward into a tube with a diameter D₀^{c}=4.4 μm after release. The tube diameter was predicted to decrease to D₁^{c}=1.1 m after heating at 600° C. followed by cooling to 20° C. FIG. 10 shows that a 2.6% average strain and a 0.18%/nm strain gradient can be established in SrTiO₃ via self-assembly of the 14.5/10 nm SrTiO₃/Si NM.

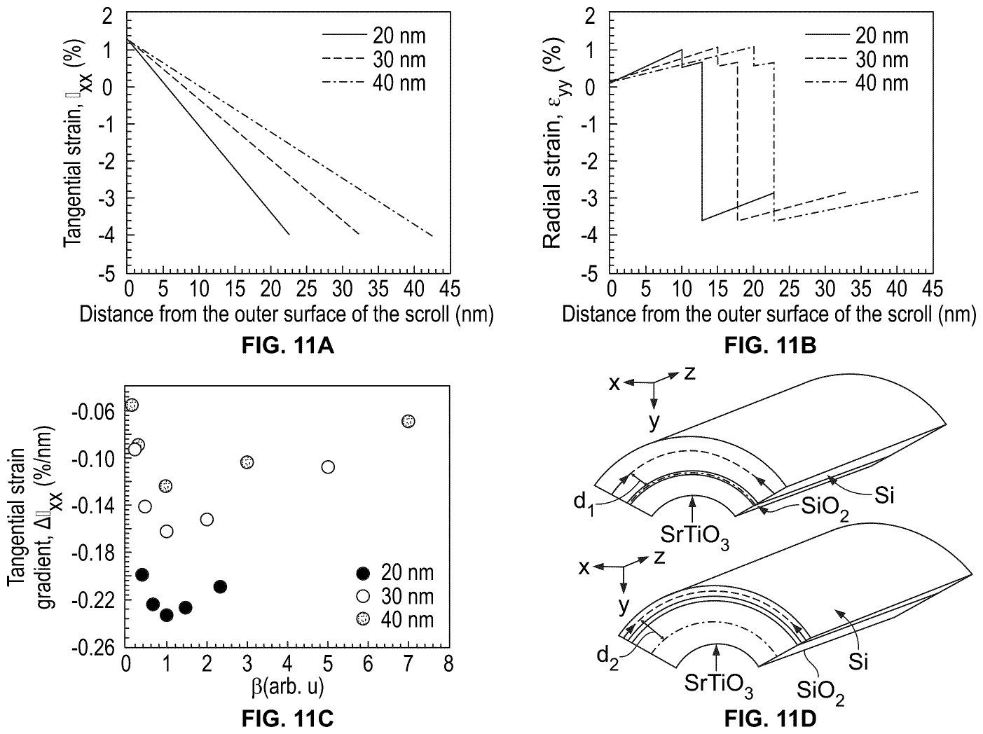

The radii and the residual strain distributions in the tube wall after heating can be selected by tailoring the total thickness of the NM and the Si-to-SrTiO₃ thickness ratio (β=t_{Si}/tSrTiO₃), as demonstrated by the results in FIG. 11. FIGs. 11 (a)-(b) shows that there is an increase in the calculated strains across the SrTiO₃/Si bilayer and strain gradients in the SrTiO₃ as the total thickness of the NM decreases. The trend in the strain as a function of thickness in FIG. 11 is consistent with the expectation that thinner SrTiO₃/Si NM exhibit higher curvature under the reasonable assumptions that deposition and reconfiguration stresses are the same for SrTiO₃ with thickness in the range of 10-30 nm. Indeed the calculated diameters for rolled-up SrTiO₃/Si NMs after heating are 0.9 μm, 1.6 μm, and 2.4 μm for total thicknesses of 20, 40, and 60 nm, respectively.

The Si-to-SrTiO₃ thickness ratio (P) also affects the axial strain gradient in the oxide layers. This effect was quantified by calculating the equilibrium diameter and the axial strain distributions in bilayer NMs with three different total thicknesses after heating at 600° C. and subsequent cooling to 20° C. The calculations were carried out at different practically realizable 3 values per each total NM thickness. FIG. 11(c) shows the axial strain gradient in the tangential direction, Δεₓₓ as a function of β at different NM thicknesses. Higher Δεₓₓ were obtained for all β in thinner NMs because they assemble in 3D structures with smaller radii of curvature due to their reduced bending stiffness. An additional key observation is that Δεₓₓ exhibits a maximum at =1. The peak strain gradient at intermediate β was justified as follows. When the SrTiO₃ undergoes densification, it relaxes inward and applies an axial force and a bending moment to the bilayer NM. The magnitude of the force is proportional to the residual stress in the SrTiO₃ and the cross-sectional area of the oxide layer. The bending moment is equal to the axial force times the distance (d) from the mean position of the applied force (i.e., the middle of the SrTiO₃) to the line crossing the bilayer NM in the middle of its thickness (see FIG. 11(d)). For β>1, the oxide layer applies a relatively small axial force but a large torque because of large d (see d=d₁ in FIG. 11(d)). For β<1, the bending moment is reduced because the axial force is applied closer to the mid-thickness of the NM (i.e., d=d₂ or the arm of the torque in FIG. 11(d) is smaller than dᵢ). The increase in bending moment at large β and its decrease at small 3 results in the NM having a minimum radius of curvature and a maximum strain gradient at intermediate values of β near 1.

Assembly and Strain Fields in SrTiO₃/LaAlO₃ μNanomembranes

The reconfiguration of amorphous oxides can impart high strain in heterostructures consisting of two complex oxides, such as a SrTiO₃/LaAlO₃ bilayer. This combination has electrical transport characteristics originating from a highly conductive channel near the interface of the two materials.

Strain affects the formation and the conductivity of stable metallic interfaces between single-crystalline and amorphous/crystalline oxides. Structural reconfiguration of complex oxides during heating may yield mass-producible strained interfaces within rolled-up tubes.

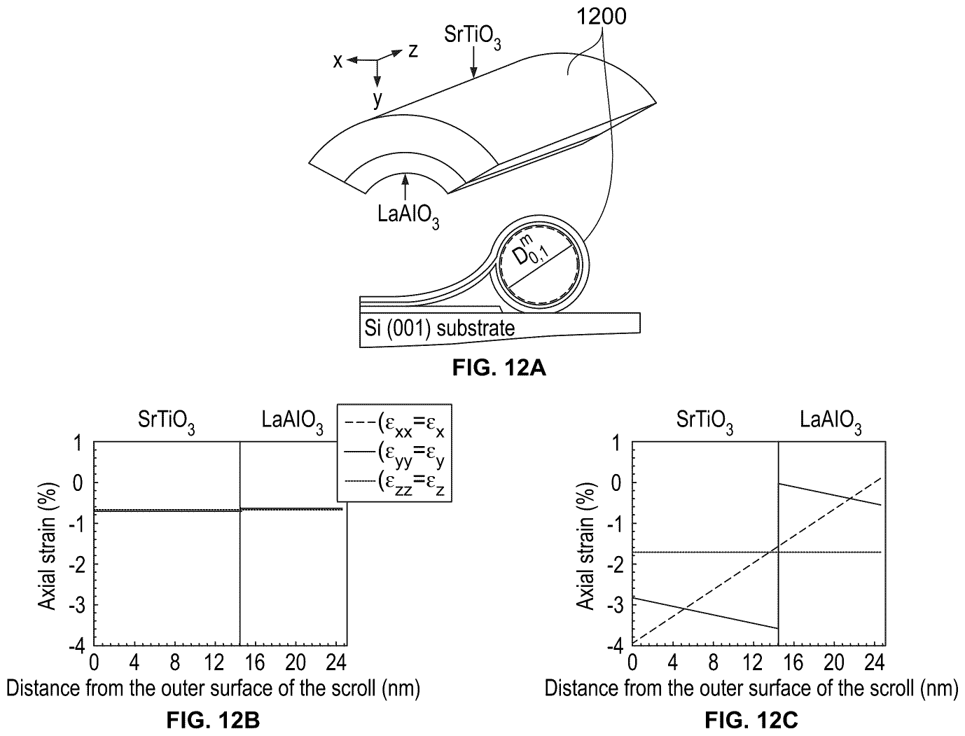

FIG. 12 shows the calculated axial strain distributions in an amorphous SrTiO₃/LaAlO₃ bilayer 1200 upon release and annealing at 600° C. For this embodiment, the previously estimated strain in as-deposited SrTiO₃, i.e., −0.7%, and assumed zero strain in the as-deposited LaAlO₃. The continuum mechanics modeling predicted that the amorphous SrTiO₃/LaAlO₃ bilayer would bend downward, i.e., towards the substrate surface, upon release, as shown in FIG. 12(a). The equilibrium tube diameter was 77.5 μm resulting in a relatively small strain and strain gradient in the NM (see FIG. 12(b)). After heating at 600° C., reconfiguration of the amorphous SrTiO₃ reduced the expected equilibrium tube diameter to 1.2 μm. FIG. 12(c) shows that the calculated strains and strain gradients are sufficiently large to affect the diffusion of oxygen vacancies and electron transport via internal polarization. Therefore, establishing tunable strains and strain gradients in complex oxides via reconfiguration-driven assembly is a viable approach to tailor ionic and electronic transport in oxide-based devices on conventional semiconductor substrates.

Broad Relevance of Complex Oxide Nanomembranes obtained via Reconfiguration-Driven Assembly.

The results and continuum mechanics calculations discussed above show that reconfiguration-driven assembly obtains rolled-up complex oxide nanomembranes with radii of curvature ranging from a few hundred nanometers to 1-2 μm. Maximum and average strains of several percentages are achievable in complex oxide NMs bent to such small radii (see FIGS. 10-12). These calculated values are well within the range of strains that affect important functional properties of complex oxides.

The strain gradients that were calculated for the embodiments of the present invention obtained by reconfiguration-driven assembly are of the order of 10⁶-10⁷ μm⁻¹ and will therefore generate an internal polarization in the range of 10⁻³ to 10 C/m. Such large internal polarization may be used to control interfacial carrier concentration and mobility in complex oxides heterostructures. Flexoelectric switching between a high and a low resistance state of the interface will be thus realizable in curved NMs. Curved oxide NMs that exhibit 10⁷ μm⁻¹ may also form the basis for nanoelectromechanical actuators with superior performance than those relying on the piezoelectric and ferroelectric effects.

An additional benefit of reconfiguration-driven assembly is in its ability to generate unique heterostructures in radial geometries. Composition and strain can be engineered in a wide range in these heterostructures, allowing broad tunability of the band-alignment within the rolled-up NM. The estimated range of strain values in the structures is sufficiently high to control the coupling of spin and charge degrees of freedom between two complex oxides or between a complex oxide and a conventional semiconductor. Spintronics and opto-spintronics are two areas that would benefit from a strain-engineered semiconductor/oxide heterostructure. Indeed, in a semiconductor/oxide heterostructure where the band-alignment is tailored to allow coherent spin-transfer across the interface, the oxide will inject and collect spin-polarized carriers from the semiconductor. The semiconductor will support the manipulation of spin via external signals to realize logic functions.

Reconfiguration of amorphous oxide layers drives the assembly of oxide-based and freestanding NMs into 3D structures with a radius of a few hundred nanometers. The crystallization of the amorphous oxide may provide for even higher stresses than are available through the reconfiguration of the amorphous structure as the thickness of amorphous SrTiO₃ thin films decreases by 13% during crystallization.

Reconfiguration-driven assembly is a versatile approach to impart large strains and strain gradients in a broad palette of complex oxides. This capability allows for manipulating and enhancing ferroelectricity, flexoelectricity, piezoelectricity, superconductivity, and ferromagnetism in complex oxides. Moreover, strain-engineered oxides may be obtained in the form of 3D structures that can be fabricated in parallel on any substrate, including large-area and single crystalline semiconductor substrates.

Reconfiguration-driven assembly of NMs also allows combining different materials in a radial geometry and through scalable processes. For example, radial superlattices of Si (or GaAs) and various complex oxides or alternating layers of different complex oxides (e.g., SrTiO₃ and LaAlO₃) may be fabricated by release and heating of bilayer NMs. A broad palette of electronic band structures and spin-orbit interactions could then be obtained by tailoring the curvature of the self-assembled NMs and the materials that the heterostructure comprises.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should, therefore, not be limited by the above-described embodiments, methods, and examples, but by all embodiments and methods within the scope and spirit of the disclosure.

What is claimed is:

1. A method of producing a radial geometry in a planar nanomembrane comprising the steps of:
providing a nanomembrane, said nanomembrane comprised of stacked layers;
said nanomembrane located on a sacrificial layer;
said sacrificial layer located on a substrate;
releasing said nanomembrane from said substrate by removing said sacrificial layer to produce a radial geometry in said nanomembrane due to the elastic relaxation of stress from two sources: (i) the a varying latticeconstant across the thickness of a semiconductor multi-layer; and (ii) stress resulting from the deposition of an amorphous layer.

2. The method of claim 1 wherein said one of amorphous oxide layer is SrTiO₃.

3. The method of claim 1 wherein one of said stacked layers is an amorphous oxide layer SrTiO₃/Si/Si₁₋ₓGeₓ.

4. The method of claim 1 wherein one of said stacked layers is an amorphous oxide layer is SrTiO₃/Si.

5. The method of claim 1 wherein one of said stacked layers is an amorphous oxide layer is SrTiO₃/LaAlO₃.

6. The method of claim 1 wherein at least one stacked layer is a is a single-crystalline layer.

7. The method of claim 1 wherein at least one stacked layer is a poly-crystalline semiconductor layer.

8. The method of claim 1 wherein said nanomembrane is formed into a tube or a scroll.

9. The method of claim 1 wherein said nanomembrane is formed into a tube having a plurality of windings.

10. The method of claim 8 further including the step of heating said nanomembrane after release to reduce the diameter of said roll.

11. The method of claim 8 further including the step of heating said nanomembrane after release to increase the number of windings of said rolled-up tube.

12. The method of claim 10 further including the step of forming a trench in said nanomembrane prior to heating said nanomembrane.

13. The method of claim 11 further including the step of forming a trench in said nanomembrane prior to heating said nanomembrane.

14. The method of claim 10 further including the step of forming a trench in said nanomembrane and said substrate prior to releasing said nanomembrane.

15. The method of claim 11 further including the step of forming a trench in said nanomembrane and said substrate prior to releasing said nanomembrane.

16. The method of claim 1 wherein said sacrificial layer is amorphous Si or Ge.

17. The method of claim 1 wherein said sacrificial layer is an intrinsic Si.

18. The method of claim 1 wherein one of said stacked layers is an oxide.

19. The method of claim 1 wherein one of said stacked layers is a metastable complex oxide.

20. The method of claim 1 wherein one of said stacked layers are amorphous oxides.
